(19) United States
(12) Patent Application Publication
(10) Pub. No.: US 2016/0351421 A1
(43) Pub. Date: Dec. 1, 2016

(54) SUBSTRATE PROCESSING APPARATUS

(71) Applicant: SCREEN Holdings Co., Ltd., Kyoto (JP)

(72) Inventors: Michinori IWAO, Kyoto (JP); Ryo MURAMOTO, Kyoto (JP)

(21) Appl. No.: 15/164,270

(22) Filed: May 25, 2016

(30) Foreign Application Priority Data
May 29, 2015 (JP) 2015-109311

(51) Int. Cl. H01L 21/67; H01L 21/687

(52) U.S. Cl. CPC H01L 21/6708; H01L 21/68764

(57) ABSTRACT

In a substrate processing apparatus, chucks and engagement parts are disposed on the upper surface of a holding base part that extends radially outward of a base supporter, and the engagement parts are located radially outward of the chucks. A generally annular lower protruding part extends radially outward from the base supporter below the holding base part. In a cup part, a guard for receiving a processing liquid from a substrate is switched between a first guard and a second guard by a guard moving mechanism moving the first guard in the up-down direction between a liquid receiving position and a retracted position. With the first guard located at the retracted position, the lower protruding part extends toward the inner peripheral edge of a first-guard canopy part. This configuration suppresses the flow of a gas between the first guard and the second guard.

### TECHNICAL FIELD

The present invention relates to a substrate processing apparatus for processing substrates.

### BACKGROUND ART

A process of manufacturing semiconductor substrates (hereinafter, simply referred to as “substrates”) conventionally involves various types of processing that is performed on substrates. For example, chemical solution processing such as etching is performed on a surface of a substrate having a resist pattern on its surface by supplying a chemical solution to the substrate. After the chemical solution processing ends, cleaning processing is performed by supplying a cleaning liquid to the substrate, and then dry processing is performed on the substrate.

In a substrate cleaning device disclosed in Japanese Patent Publication No. 3621568 (Document 1), for example, a cover member is placed on a spin chuck that holds a wafer horizontally, and rotated along with the wafer. When performing cleaning processing on the substrate, first a cleaning liquid is supplied from an upper nozzle disposed above and spaced from the cover member to the substrate that is being rotated, through an opening provided in the cover member at the center of rotation. Examples of cleaning liquids that are used include hydrofluoric acid, hydrochloric acid, sulfuric acid, phosphoric acid, ammonia, and a hydrogen peroxide solution. Then, deionized water is supplied from the upper nozzle to the rotating substrate to wash away the cleaning liquid adhering to the substrate. When subsequently performing dry processing on the substrate, a nitrogen (N) gas is ejected from the upper nozzle and supplied to the wafer through the opening of the cover member. This reduces the oxygen concentration in the space between the cover member and the wafer and accelerates drying of the substrate.

A substrate liquid processing apparatus disclosed in Japanese Patent Application Laid-Open No. 2011-254019 (Document 2) includes a liquid guide upper cup, a liquid guide center cup, and a liquid guide lower cup that receive a liquid dispersed from a substrate that is being rotated, around a pedestal for holding the substrate. These cups are each movable in the up-down direction. Each cup has a cylindrical vertical part and an inclined part that is inclined radially inward from the upper end of the vertical part. In the lower part of the pedestal is provided a support protruding part that is fixed integrally with the pedestal and extends radially outward of the outer peripheral edge of the substrate. In the substrate liquid processing apparatus, the cup for receiving the liquid from the substrate is switched between the liquid guide upper cup, the liquid guide center cup, and the liquid guide lower cup when the type of the liquid dispersed from the substrate changes. When the liquid from the substrate is received by the liquid guide upper cup or the liquid guide center cup, the inner peripheral edge of the inclined part of the liquid guide lower cup is in contact with the support protruding part provided in the lower part of the pedestal. This suppresses the occurrence of a situation in which the atmosphere inside the liquid guide lower cup rises and enters inside the liquid guide upper cup and the liquid guide center cup.

In the substrate cleaning device of Document 1, the spin chuck extends radially outward of chucks that support the outer peripheral edge of the substrate, and supports the cover member radially outward of these chucks. This configuration increases the size of the spin chuck in the radial direction and accordingly increases the load on a rotation mechanism for rotating the spin chuck.

In order to reduce the load on the rotation mechanism, it is conceivable to reduce the outer diameter of the lower part of the spin chuck while maintaining the shape of the upper part (i.e., portion in the vicinity of the upper surface) of the spin chuck. In the substrate liquid processing apparatus of Document 2, however, if the outer diameter of the lower part of the pedestal is reduced, the inner peripheral edge of the inclined part of the liquid guide lower cup will be spaced radially outward from the support protruding part of the lower part of the pedestal when the liquid from the substrate is received by the liquid guide upper cup or the liquid guide center cup. This causes the atmosphere inside the liquid guide lower cup to rise and enter inside the liquid guide upper cup or the liquid guide center cup, resulting in a mixture of atmospheres of different types of processing liquids. If suction of the atmosphere in the liquid guide upper cup or the liquid guide center cup is suppressed in order to prevent a rise in the atmosphere inside the liquid guide lower cup, uniformity of the strength of suction in each cup is deteriorated.

### SUMMARY OF INVENTION

The present invention is intended for a substrate processing apparatus for processing a substrate, and it is an object of the present invention to suppress the flow of a gas between guards in a cup part that includes a plurality of guards.

A substrate processing apparatus according to the present invention includes a substrate holder for holding a substrate in a horizontal position, an opposing member that is held by the substrate holder, opposes an upper surface of the substrate, and has an opposing-member opening in a central part, a substrate rotation mechanism disposed below the substrate holder and for rotating the substrate and the opposing member along with the substrate holder about a central axis pointing in an up-down direction, a rotation-mechanism housing part for housing the substrate rotation mechanism below the substrate holder, a processing liquid supply part for supplying a processing liquid to the upper surface of the substrate through the opposing-member opening, and a cup part disposed around the substrate holder and for receiving a processing liquid from the substrate. The substrate holder includes a base supporter, a disk-shaped holding base part supported from below by the base supporter and extending radially outward of the base supporter, a plurality of chucks that are disposed on an upper surface of the holding base part and support the substrate, and an opposing-member supporter that is disposed radially outward of the plurality of chucks on the upper surface of the holding base part and supports the opposing member. The cup part includes a first guard having a cylindrical first-guard side wall part and an annular plate-like first-guard canopy part that extends radially inward from an upper end portion of the first-guard side wall part, a second guard having a cylindrical second-guard side wall part that is located radially outward of the first-guard side wall part, and an annular plate-like second-guard canopy part that extends radially inward from an upper end portion of the second-guard side wall part above the first-guard canopy part, a guard moving mechanism for switching a guard for receiving a processing liquid from the substrate between the first guard and the second guard by moving the first guard in the up-down direction between a liquid receiving position at which the first guard receives the processing liquid from the substrate and a retracted position that is below the liquid receiving position, and a discharge port through which gas in the first guard and the second guard is exhausted. An inner diameter of the first-guard canopy part and an inner diameter of the second-guard canopy part are greater than an outer diameter of the holding base part and an outer diameter of the opposing member, and an annular lower protruding part is provided to extend radially outward from either the base supporter or the rotation-mechanism housing part below the holding base part toward an inner peripheral edge of the first-guard canopy part in a state in which the first guard is located at the retracted position. This substrate processing apparatus can suppress the flow of a gas between guards in the cup part that includes a plurality of guards.

In a preferred embodiment of the present invention, the substrate processing apparatus further includes a purge gas supply part for supplying a purge gas to a space between the base supporter of the substrate holder and the rotation-mechanism housing part and producing an airflow flowing radially outward from the central part. The lower protruding part is provided on the base supporter.

In another preferred embodiment of the present invention, the outer diameter of the opposing member is greater than the outer diameter of the holding base part, and an outer diameter of the lower protruding part is greater than the outer diameter of the holding base part and less than or equal to the outer diameter of the opposing member.

In another preferred embodiment of the present invention, the opposing member includes an annular plate-like opposing-member canopy part that opposes the upper surface of the substrate and has the opposing-member opening in the central part, and a cylindrical opposing-member side wall part that extends downward from an outer periphery of the opposing-member canopy part, and a lower end of the opposing-member side wall part is located below the upper surface of the holding base part or at the same position as the upper surface of the holding base part in the up-down direction.

Another substrate processing apparatus according to the present invention includes a substrate holder for holding a substrate in a horizontal position, an opposing member that is held by the substrate holder, opposes an upper surface of the substrate, and has an opposing-member opening in a central part, a substrate rotation mechanism disposed below the substrate holder and for rotating the substrate along with the substrate holder about a central axis pointing in an up-down direction, a processing liquid supply part for supplying a processing liquid to the upper surface of the substrate through the opposing-member opening, and a cup part disposed around the substrate holder and for receiving a processing liquid from the substrate. The substrate holder includes a holding base part, a plurality of chucks that are disposed on an upper surface of the holding base part and support the substrate, and an opposing-member supporter that is disposed radially outward of the plurality of chucks on the upper surface of the holding base part and supports the opposing member. The cup part includes a first guard having a cylindrical first-guard side wall part and an annular plate-like first-guard canopy part that extends radially inward from an upper end portion of the first-guard side wall part, a second guard having a cylindrical second-guard side wall part that is located radially outward of the first-guard side wall part, and an annular plate-like second-guard canopy part that extends radially inward from an upper end portion of the second-guard side wall part above the first-guard canopy part, a guard moving mechanism for switching a guard for receiving a processing liquid from the substrate between the first guard and the second guard by moving the first guard in the up-down direction between a liquid receiving position at which the first guard receives the processing liquid from the substrate and a retracted position that is below the liquid receiving position, and a discharge port through which gas in the first guard and the second guard is exhausted. The opposing member includes an annular plate-like opposing-member canopy part that opposes the upper surface of the substrate and has the opposing-member opening in the central part, and a cylindrical opposing-member side wall part that extends downward from an outer periphery of the opposing-member canopy part. An inner diameter of the first-guard canopy part and an inner diameter of the second-guard canopy part are greater than an outer diameter of the holding base part and an outer diameter of the opposing member. A lower end of the opposing-member side wall part is located below the upper surface of the holding base part or at the same position as the upper surface of the holding base part in the up-down direction. An inner peripheral edge of the first-guard canopy part opposes an outer surface of the holding base part in a radial direction in a state in which the first guard is located at the retracted position. This substrate processing apparatus can suppress the flow of a gas between guards in the cup part that includes a plurality of guards.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a cross-sectional view of a substrate processing apparatus according to a first embodiment;

FIG. 2 is a cross-sectional view of the substrate processing apparatus;

FIG. 3 is a block diagram of a gas-liquid supply part;

FIG. 4 is an enlarged cross-sectional view of part of a processing liquid nozzle;

FIG. 5 is a flowchart of processing performed on a substrate;

FIG. 6 is a cross-sectional view of the substrate processing apparatus;

FIG. 7 is a cross-sectional view of a substrate processing apparatus according to a second embodiment; and

FIG. 8 is a cross-sectional view of a substrate processing apparatus according to a third embodiment.

### DESCRIPTION OF EMBODIMENTS

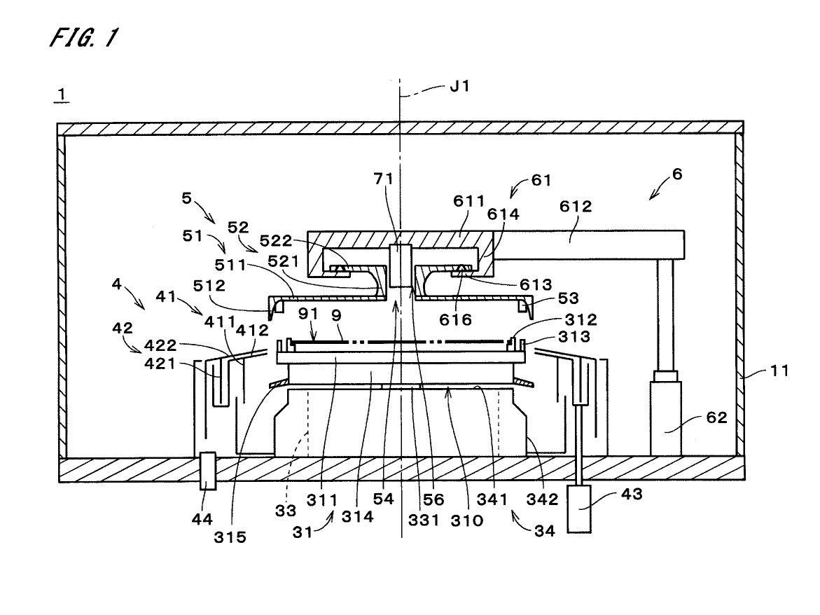

FIG. 1 is a cross-sectional view of a configuration of a substrate processing apparatus 1 according to a first embodiment of the present invention. The substrate processing apparatus 1 is a single wafer processing apparatus for processing semiconductor substrates 9 (hereinafter, simply referred to as “substrates 9”) one at a time. The substrate processing apparatus 1 includes a substrate holder 31, a substrate rotation mechanism 33, a cup part 4, a top plate 5, an opposing-member moving mechanism 6, and a processing liquid nozzle 71, and these constituent elements are housed inside a housing 11.

The substrate holder 31 holds a substrate 9 in a horizontal position. The substrate holder 31 includes a holding base part 311, a plurality of chucks 312, a plurality of engagement parts 313, a base supporter 314, and a lower protruding part 315. The substrate 9 is disposed above the holding base part 311. The holding base part 311 and the base supporter 314 are generally disk-shaped members centered on a central axis J1 pointing in the up-down direction. The holding base part 311 is disposed above the base supporter 314 and supported from below by the base supporter 314. The outer diameter of the holding base part 311 is greater than the outer diameter of the base supporter 314. The holding base part 311 extends radially outward of the base supporter 314 along the entire circumference centered on the central axis J1. The holding base part 311 is made of, for example, fluorocarbon resin having a relatively high chemical resistance. The base supporter 314 is made of, for example, relatively lightweight and high-strength vinyl chloride.

The lower protruding part 315 is a generally annular member centered on the central axis J1 and extends radially outward from the side surface of the base supporter 314. The lower protruding part 315 is provided below and spaced from the holding base part 311. The outer diameter of the lower protruding part 315 is greater than the outer diameter of the holding base part 311 and less than or equal to the outer diameter of the top plate 5. In the example illustrated in FIG. 1, the lower protruding part 315 extends radially outward from the lower end of the base supporter 314. The upper and lower surfaces of the lower protruding part 315 are inclined surfaces that are inclined downward outwardly in the radial direction.

The chucks 312 are generally equiangularly spaced from one another about the central axis J1 and circumferentially arranged on the outer periphery of the upper surface of the holding base part 311. In the substrate holder 31, the chucks 312 support the outer edge of the substrate 9. A structure for driving each chuck 312 is provided inside the base supporter 314. The engagement parts 313 are generally equiangularly spaced from one another about the central axis J1 and circumferentially arranged on the outer periphery of the upper surface of the holding base part 311. The engagement parts 313 are disposed radially outward of the chucks 312.

The substrate rotation mechanism 33 is housed in a rotation-mechanism housing part 34. The substrate rotation mechanism 33 and the rotation-mechanism housing part 34 are disposed below the substrate holder 31. The substrate rotation mechanism 33 rotates the substrate 9 along with the substrate holder 31 about the central axis J1.

The rotation-mechanism housing part 34 has a generally annular plate-like upper surface 341 that covers the top of the substrate rotation mechanism 33, and a generally cylindrical side surface 342 that covers the side of the substrate rotation mechanism 33. The upper surface 341 of the rotation-mechanism housing part 34 has, in the central part, an opening in which a rotary shaft 331 of the substrate rotation mechanism 33 is inserted. The rotary shaft 331 is connected to the lower surface of the base supporter 314. The upper surface 341 of the rotation-mechanism housing part 34 is radially spaced from the rotary shaft 331 and extends radially outward. The upper surface 341 of the rotation-mechanism housing part 34 opposes the lower surface of the base supporter 314 in the up-down direction with a gap between these surfaces. In the following description, this gap, i.e., the space between the upper surface 341 of the rotation-mechanism housing part 34 and the lower surface of the base supporter 314, is referred to as a “below-holder gap 310.”

The cup part 4 is an annular member centered on the central axis J1 and disposed radially outward of the substrate 9 and the substrate holder 31. The cup part 4 is disposed along the entire circumferences of the substrate 9 and the substrate holder 31 and receives, for example, a processing liquid dispersed from the substrate 9 to the surroundings. The cup part 4 includes a first guard 41, a second guard 42, a guard moving mechanism 43, and a discharge port 44.

The first guard 41 includes a first-guard side wall part 411 and a first-guard canopy part 412. The first-guard side wall part 411 has a generally cylindrical shape centered on the central axis J1. The first-guard canopy part 412 has a generally annular plate-like shape centered on the central axis J1 and extends radially inward from the upper end of the first-guard side wall part 411. The second guard 42 includes a second-guard side wall part 421 and a second-guard canopy part 422. The second-guard side wall part 421 has a generally cylindrical shape centered on the central axis J1 and is located radially outward of the first-guard side wall part 411. The second-guard canopy part 422 has a generally annular plate-like shape centered on the central axis J1 and extends radially inward from the upper end of the second-guard side wall part 421 above the first-guard canopy part 412.

The inner diameter of the first-guard canopy part 412 and the inner diameter of the second-guard canopy part 422 are slightly greater than the outer diameter of the holding base part 311 of the substrate holder 31 and the outer diameter of the top plate 5. The upper and lower surfaces of the first-guard canopy part 412 are inclined surfaces that are inclined downward outwardly in the radial direction. The upper and lower surfaces of the second-guard canopy part 422 are also inclined surfaces that are inclined downward outwardly in the radial direction.

The guard moving mechanism 43 switches the guard for receiving a processing liquid or the like from the substrate 9 between the first guard 41 and the second guard 42 by moving the first guard 41 in the up-down direction. The processing liquid or the like received by the first guard 41 and the second guard 42 of the cup part 4 is discharged through the discharge port 44 to the outside of the housing 11. The gas in the first guard 41 and the second guard 42 are also exhausted through the discharge port 44 to the outside of the housing 11.

The top plate 5 is a generally circular member in a plan view. The top plate 5 is an opposing member that opposes the upper surface 91 of the substrate 9 and acts as a shield plate that shields the top of the substrate 9. The outer diameter of the top plate 5 is greater than the outer diameter of the substrate 9 and the outer diameter of the holding base part 311. The top plate 5 includes an opposing-member body 51, a held part 52, and a plurality of engagement parts 53. The opposing-member body 51 includes an opposing-member canopy part 511 and an opposing-member side wall part 512. The opposing-member canopy part 511 is a generally annular plate-like member centered on the central axis J1 and opposes the upper surface 91 of the substrate 9. The opposing-member canopy part 511 has an opposing-member opening 54 in the central part. The opposing-member opening 54 is, for example, generally circular in a plan view. The diameter of the opposing-member opening 54 is sufficiently smaller than the diameter of the substrate 9. The opposing-member side wall part 512 is a generally cylindrical member centered on the central axis J1 and extends downward from the outer periphery of the opposing-member canopy part 511.

The engagement parts 53 are generally equiangularly spaced from one another about the central axis J1 and circumferentially arranged on the outer periphery of the lower surface of the opposing-member canopy part 511. The engagement parts 53 are disposed radially inward of the opposing-member side wall part 512.

The held part 52 is connected to the upper surface of the opposing-member body 51. The held part 52 includes an opposing-member cylindrical part 521 and an opposing-member flange part 522. The opposing-member cylindrical part 521 is a generally tubular part that protrudes upward from the periphery of the opposing-member opening 54 of the opposing-member body 51. The opposing-member cylindrical part 521 has, for example, a generally cylindrical shape centered on the central axis J1. The opposing-member flange part 522 extends annularly and radially outward from the upper end of the opposing-member cylindrical part 521. The opposing-member flange part 522 has, for example, a generally annular plate-like shape centered on the central axis J1.

The opposing-member moving mechanism 6 includes an opposing-member holder 61 and an opposing-member elevating mechanism 62. The opposing-member holder 61 holds the held part 52 of the top plate 5. The opposing-member holder 61 includes a holder body 611, a body supporter 612, a flange supporter 613, and a supporter connector 614. The holder body 611 has, for example, a generally disk-like shape centered on the central axis J1. The holder body 611 covers the top of the opposing-member flange part 522 of the top plate 5. The body supporter 612 is a rod-like arm that extends generally horizontally. One end of the body supporter 612 is connected to the holder body 611, and the other end is connected to the opposing-member elevating mechanism 62.

The processing liquid nozzle 71 protrudes downward from the central part of the holder body 611. The processing liquid nozzle 71 is inserted in the opposing-member cylindrical part 521 in a non-contact state. In the following description, the space between the processing liquid nozzle 71 and the opposing-member cylindrical part 521 is referred to as a “nozzle gap 56.”

The flange supporter 613 has, for example, a generally annular plate-like shape centered on the central axis J1. The flange supporter 613 is located below the opposing-member flange part 522. The inner diameter of the flange supporter 613 is smaller than the outer diameter of the opposing-member flange part 522 of the top plate 5. The outer diameter of the flange supporter 613 is greater than the outer diameter of the opposing-member flange part 522 of the top plate 5. The supporter connector 614 has, for example, a generally cylindrical shape centered on the central axis J1. The supporter connector 614 connects the flange supporter 613 and the holder body 611 around the opposing-member flange part 522. In the opposing-member holder 61, the holder body 611 is a holder upper part that opposes the upper surface of the opposing-member flange part 522 in the up-down direction, and the flange supporter 613 is a holder lower part that opposes the lower surface of the opposing-member flange part 522 in the up-down direction.

With the top plate 5 located at the position illustrated in FIG. 1, the flange supporter 613 is in contact with and supports the outer periphery of the opposing-member flange part 522 of the top plate 5 from the underside. In other words, the opposing-member flange part 522 is held by the opposing-member holder 61 of the opposing-member moving mechanism 6. Thus, the top plate 5 is suspended from the opposing-member holder 61 above the substrate 9 and the substrate holder 31. In the following description, the position of the top plate 5 in the up-down direction in FIG. 1 is referred to as a “first position.” The top plate 5 located at the first position is held by the opposing-member moving mechanism 6 and spaced above the substrate holder 31.

The flange supporter 613 is provided with a movement restricting part 616 for restricting positional shift of the top plate 5 (i.e., movement and rotation of the top plate 5). In the example illustrated in FIG. 1, the movement restricting part 616 is a protruding part that protrudes upward from the upper surface of the flange supporter 613. Positional shift of the top plate 5 is limited by inserting the movement restricting part 616 in a hole provided in the opposing-member flange part 522.

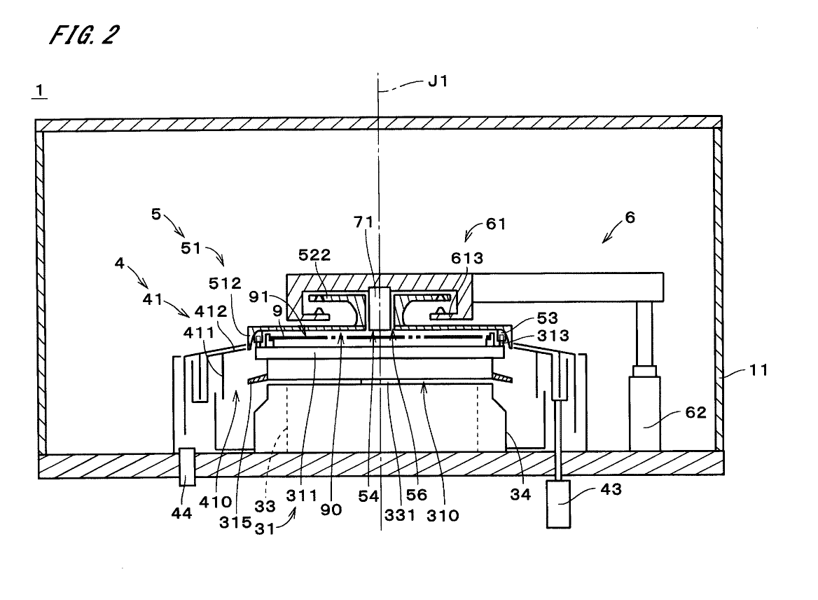

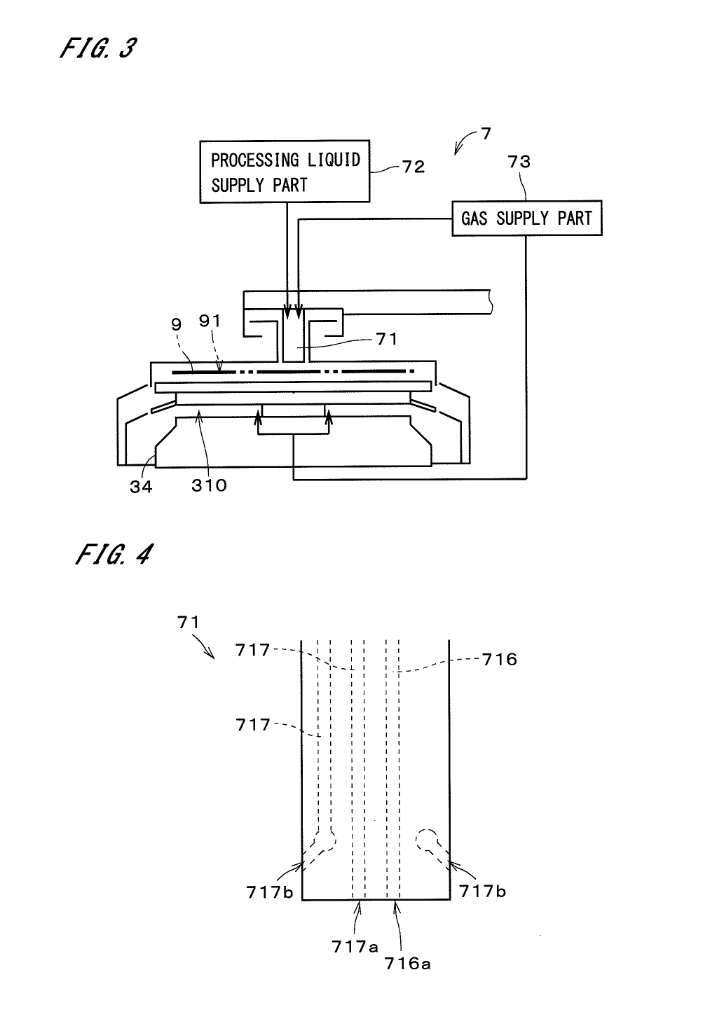

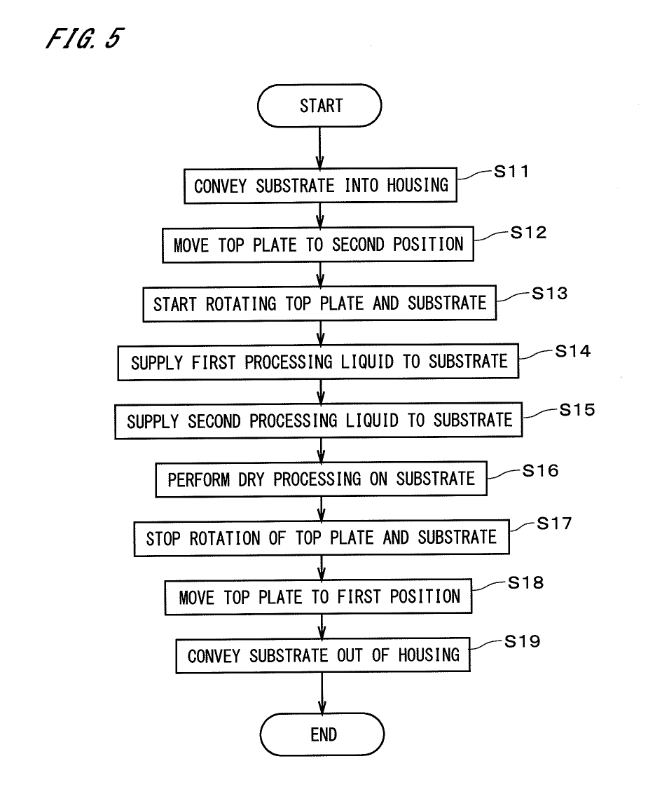

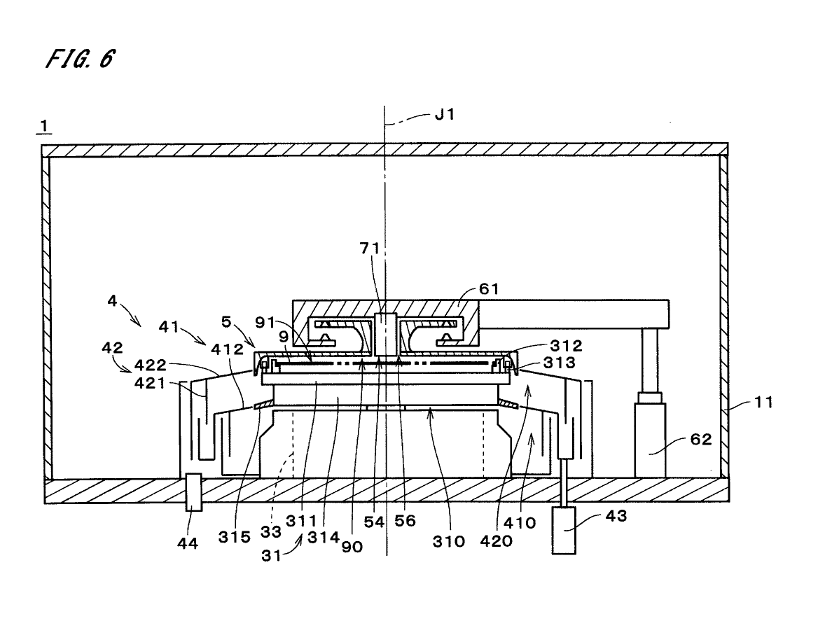

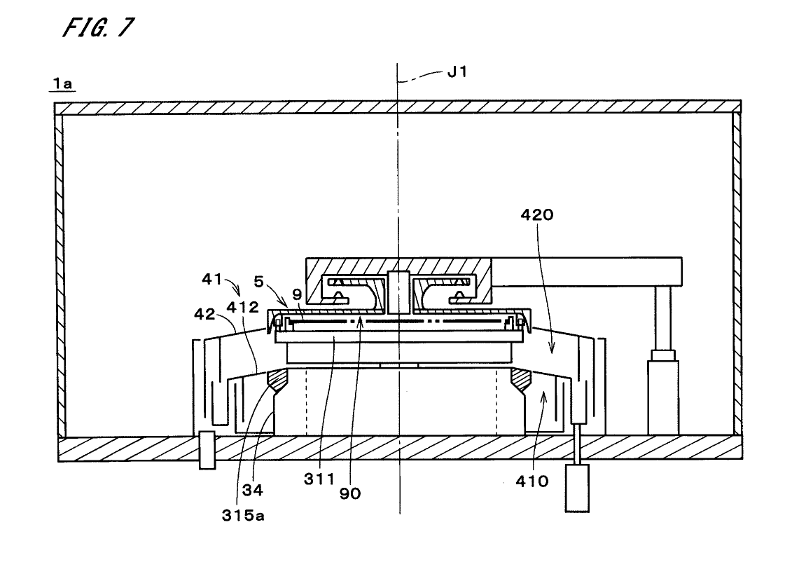

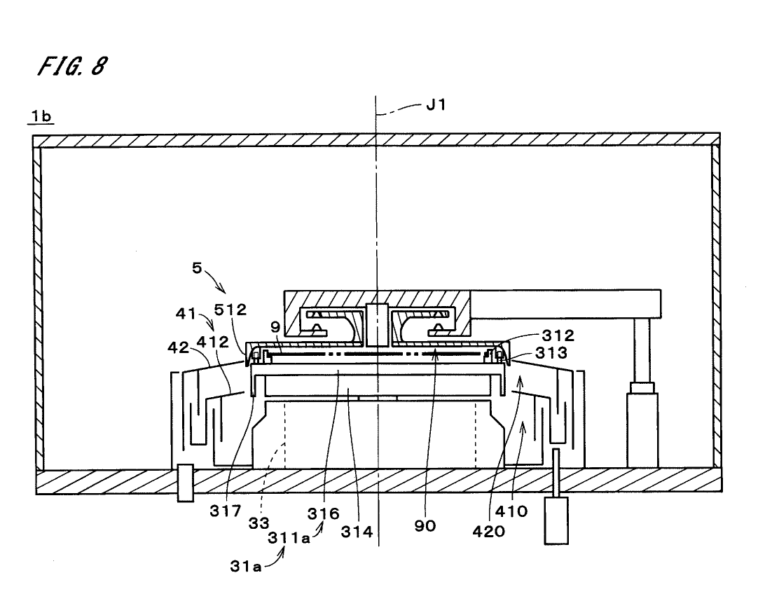

The opposing-member elevating mechanism 62 moves the top plate 5 along with the opposing-member holder 61 in the up-down direction. FIG. 2 is a cross-sectional view illustrating a state in which the top plate 5 has been moved down from the first position illustrated in FIG. 1. In the following description, the position of the top plate 5 in the up-down direction in FIG. 2 is referred to as a “second position.” That is, the opposing-member elevating mechanism 62 moves the top plate 5 relative to the substrate holder 31 between the first position and the second position in the up-down direction. The second position is a position below the first position. In other words, the second position is a position at which the top plate 5 is closer to the substrate holder 31 in the up-down direction than at the first position.

With the top plate 5 located at the second position, the engagement parts 53 of the top plate 5 are respectively engaged with the engagement parts 313 of the substrate holder 31. The engagement parts 53 are supported from below by the engagement parts 313. In other words, the engagement parts 313 are opposing-member supporters that support the top plate 5. For example, the engagement parts 313 are pins that extend generally parallel to the up-down direction, and the upper ends of the engagement parts 313 fit into upwardly opening recesses that are formed in the lower ends of the engagement parts 53. The opposing-member flange part 522 of the top plate 5 is spaced above the flange supporter 613 of the opposing-member holder 61. Thus, the top plate 5 located at the second position is held by the substrate holder 31 and spaced from the opposing-member moving mechanism 6 (i.e., without contacting with the opposing-member moving mechanism 6).

With the top plate 5 held by the substrate holder 31, the lower end of the opposing-member side wall part 512 of the top plate 5 is located below the upper surface of the holding base part 311 of the substrate holder 31 or at the same position as the upper surface of the holding base part 311 in the up-down direction. When the substrate rotation mechanism 33 is driven with the top plate 5 located at the second position, the top plate 5 rotates along with the substrate 9 and the substrate holder 31. In other words, the top plate 5 located at the second position is rotatable along with the substrate 9 and the substrate holder 31 about the central axis J1 by the substrate rotation mechanism 33.

FIG. 3 is a block diagram of a gas-liquid supply part 7 that is related to the supply of gas and processing liquid in the substrate processing apparatus 1. The gas-liquid supply part 7 includes the processing liquid nozzle 71, a processing liquid supply part 72, and a gas supply part 73. The processing liquid supply part 72 is connected to the processing liquid nozzle 71 and supplies a processing liquid to the processing liquid nozzle 71. The gas supply part 73 is connected to the processing liquid nozzle 71 and supplies a gas to the processing liquid nozzle 71. The gas supply part 73 is also connected to the rotation-mechanism housing part 34 and supplies a gas to the below-holder gap 310 through the rotation-mechanism housing part 34.

In the substrate processing apparatus 1, various types of processing liquids are used as processing liquids. The processing liquid may, for example, be a chemical solution (e.g., a polymer removing solution or an etchant such as hydrofluoric acid or an aqueous solution of tetramethyl ammonium hydroxide) used in chemical solution processing of the substrate 9. The processing liquid may, for example, be a cleaning liquid such as deionized water (DIW) or carbonated water that is used in the cleaning processing of the substrate 9. The processing liquid may, for example, be isopropyl alcohol (IPA) that is supplied to replace the liquid on the substrate 9. A gas supplied from the gas supply part 73 may, for example, be an inert gas such as a nitrogen (N₂) gas. Alternatively, the gas supply part 73 may supply various gases other than an inert gas.

FIG. 4 is an enlarged cross-sectional view of part of the processing liquid nozzle 71. The processing liquid nozzle 71 may be made of, for example, tetrafluoroethylene-perfluoroalkylvinylether copolymer (PFA). The processing liquid nozzle 71 includes a processing liquid passage 716 and two gas passages 717. The processing liquid passage 716 is connected to the processing liquid supply part 72 illustrated in FIG. 3. The two gas passages 717 are connected to the gas supply part 73 illustrated in FIG. 3.

The processing liquid supplied from the processing liquid supply part 72 to the processing liquid passage 716 illustrated in FIG. 4 is ejected downward from an ejection port 716a that is provided in the lower end surface of the processing liquid nozzle 71. When a plurality of types of processing liquids are ejected from the processing liquid nozzle 71, the processing liquid nozzle 71 may include a plurality of processing liquid passages 716 that correspond respectively to the plurality of types of processing liquids, and the plurality of types of processing liquids may be ejected respectively from a plurality of ejection ports 716a.

The inert gas supplied from the gas supply part 73 to the gas passage 717 in the center of the nozzle (the gas passage 717 on the right in FIG. 4) is supplied (e.g., jetted) downward from a lower-surface jet opening 717a that is provided in the lower end surface of the processing liquid nozzle 71. The inert gas supplied from the gas supply part 73 to the gas passage 717 in the outer periphery of the nozzle is supplied to the surroundings from a plurality of side-surface jet openings 717b that are provided in the side surface of the processing liquid nozzle 71.

The side-surface jet openings 717b are circumferentially arrayed at generally equiangular intervals. The side-surface jet openings 717b are connected to a peripheral passage that extends peripherally from the lower ends of the gas passages 717. The inert gas supplied from the gas supply part 73 is supplied (e.g., jetted) diagonally downward from the side-surface jet openings 717b. Note that there may be only one side-surface jet opening 717b.

The processing liquid supplied from the processing liquid supply part 72 (see FIG. 3) is ejected from the ejection port 716a of the processing liquid nozzle 71 through the opposing-member opening 54 illustrated in FIG. 2 toward the upper surface 91 of the substrate 9. In other words, the processing liquid nozzle 71 supplies the processing liquid supplied from the processing liquid supply part 72 to the upper surface 91 of the substrate 9 through the opposing-member opening 54. In the substrate processing apparatus 1, the processing liquid nozzle 71 may protrude downward through the opposing-member opening 54 of the opposing-member body 51. In other words, the tip end of the processing liquid nozzle 71 may be located below the lower edge of the opposing-member opening 54. The processing liquid supplied from the processing liquid supply part 72 flows down in the processing liquid nozzle 71 through the opposing-member opening 54 and is ejected from the ejection port 716a (see FIG. 4) of the processing liquid nozzle 71 toward the upper surface 91 of the substrate 9. Supplying the processing liquid through the opposing-member opening 54 includes not only a state in which the processing liquid that is ejected from the processing liquid nozzle 71 above the opposing-member opening 54 passes through the opposing-member opening 54, but also a state in which the processing liquid is ejected through the processing liquid nozzle 71 that is inserted in the opposing-member opening 54.

Part of the inert gas supplied from the gas supply part 73 (see FIG. 3) to the processing liquid nozzle 71 is supplied from the lower-surface jet opening 717a (see FIG. 4) of the processing liquid nozzle 71 through the opposing-member opening 54 to a space (hereinafter, referred to as a “processing space 90”) between the top plate 5 and the substrate 9. Part of the inert gas supplied from the gas supply part 73 to the processing liquid nozzle 71 is supplied from the side-surface jet openings 717b (see FIG. 4) of the processing liquid nozzle 71 to the nozzle gap 56. In the nozzle gap 56, the inert gas from the gas supply part 73 is supplied diagonally downward from the side surface of the processing liquid nozzle 71, flows downward, and is supplied to the processing space 90.

In the substrate processing apparatus 1, the processing of the substrate 9 is preferably performed in the state in which the processing space 90 is in an inert gas atmosphere after the supply of the inert gas from the processing liquid nozzle 71 to the processing space 90. In other words, the gas supplied from the gas supply part 73 to the processing space 90 is a treatment atmospheric gas. The treatment atmospheric gas includes a gas that is supplied from the processing liquid nozzle 71 to the nozzle gap 56 and supplied through the nozzle gap 56 to the processing space 90.

The inert gas supplied from the gas supply part 73 to the rotation-mechanism housing part 34 is supplied downward along the rotary shaft 331 to the below-holder gap 310 and spreads radially outward in the below-holder gap 310. This produces an airflow of the inert gas that flows radially outward from the central part of the below-holder gap 310, and accordingly the space around the rotary shaft 331 and the below-holder gap 310 are purged by the inert gas. That is, the gas supplied to the below-holder gap 310 is a purge gas for sealing the rotary shaft 331. The purge gas that has reached the outer periphery of the below-holder gap 310 flows radially outward along the lower surface of the lower protruding part 315. In the example illustrated in FIG. 3, the gas supply part 73 serves as a purge gas supply part that is a supply source of the purge gas, and also serves as a treatment-atmospheric-gas supply part that is a supply source of the treatment atmospheric gas. The treatment atmospheric gas and the purge gas are gases of the same type. Note that the treatment atmospheric gas and the purge gas may be different types of gases.

Next, an exemplary procedure of processing performed on the substrate 9 by the substrate processing apparatus 1 will be described with reference to FIG. 5. First, with the top plate 5 located at the first position illustrated in FIG. 1, the substrate 9 is conveyed into the housing 11 and held by the substrate holder 31 (step S11). At this time, the top plate 5 is held by the opposing-member holder 61 of the opposing-member moving mechanism 6.

Then, the opposing-member holder 61 is moved down by the opposing-member elevating mechanism 62. Thus, the top plate 5 is moved down from the first position to the second position and held by the substrate holder 31 as illustrated in FIG. 2 (step S12). Then, the supply of an inert gas (i.e., treatment atmospheric gas) from the gas supply part 73 through the processing liquid nozzle 71 to the nozzle gap 56 and the processing space 90 is started. Also, the supply of an inert gas (i.e., purge gas) from the gas supply part 73 through the rotation-mechanism housing part 34 to the below-holder gap 310 is started.

Then, the substrate rotation mechanism 33 starts rotating the substrate holder 31, the substrate 9, and the top plate 5 (step S13). The supply of inert gas from the processing liquid nozzle 71 and the supply of the inert gas to the below-holder gap 310 is continued after step S13. Then, the first processing liquid is supplied from the processing liquid supply part 72 to the processing liquid nozzle 71 and supplied through the opposing-member opening 54 of the top plate 5 located at the second position to the central part of the upper surface 91 of the substrate 9 that is being rotated (step S14).

The first processing liquid supplied from the processing liquid nozzle 71 to the central part of the substrate 9 is spread radially outward from the central part of the substrate 9 over the entire upper surface 91 of the substrate 9 by the rotation of the substrate 9. The first processing liquid is dispersed radially outward from the outer edge of the substrate 9 and received by the first guard 41 of the cup part 4. The position of the first guard 41 in the up-down direction in FIG. 2 is a position at which the first guard 41 receives the processing liquid from the substrate 9, and therefore referred to as a “liquid receiving position” in the following description.

With the first guard 41 located at the liquid receiving position, the atmosphere in the inner space of the first guard 41 (hereinafter, referred to as a “first-guard inner space 410”) is discharged through the discharge port 44 to the outside of the housing 11. The atmosphere in the processing space 90 is discharged through the first-guard inner space 410 and the discharge port 44 to the outside of the housing 11. The atmosphere in the processing space 90 and the first-guard inner space 410 contains, for example, a mist of the first processing liquid. The first-guard inner space 410 is an annular space surrounded by the first guard 41 and the substrate holder 31. Specifically, the first-guard inner space 410 indicates a space that is below the first-guard canopy part 412, radially inward of the first-guard side wall part 411, and radially outward of the inner peripheral edge of the first-guard canopy part 412. With the first guard 41 located at the liquid receiving position, the purge gas flowing radially outward from the below-holder gap 310 flows into the first-guard inner space 410 along the lower surface of the lower protruding part 315 and is discharged to the outside of the housing 11 through the discharge port 44. In the substrate processing apparatus 1, the first processing liquid is applied to the substrate 9 for a predetermined period of time, thus ending the processing of the substrate 9 using the first processing liquid.

The first processing liquid may, for example, be a chemical solution such as a polymer removing liquid or an etchant, and in step S14, chemical solution processing is performed on the substrate 9. Note that the supply of the first processing liquid (step S14) may be performed before the rotation of the substrate 9 is started (step S13). In this case, a puddle of the first processing liquid is formed on the entire upper surface 91 of the substrate 9 that is in a stationary state, and puddling using the first processing liquid is performed.

When the processing of the substrate 9 using the first processing liquid has ended, the supply of the first processing liquid from the processing liquid nozzle 71 is stopped. The first guard 41 is then moved down by the guard moving mechanism 43 and located at a retracted position that is below the aforementioned liquid receiving position as illustrated in FIG. 6. Accordingly, the guard for receiving the processing liquid from the substrate 9 is switched from the first guard 41 to the second guard 42. That is, the guard moving mechanism 43 is a guard switching mechanism for switching the guard for receiving the processing liquid from the substrate 9 between the first guard 41 and the second guard 42 by moving the first guard 41 between the liquid receiving position and the retracted position in the up-down direction.

With the first guard 41 located at the retracted position, the lower protruding part 315 that protrudes radially outward from the base supporter 314 extends toward the inner peripheral edge of the first-guard canopy part 412. The outer peripheral edge of the lower protruding part 315 and the inner peripheral edge of the first-guard canopy part 412 are located at appropriately the same position in the up-down direction and radially oppose each other with a slight gap therebetween.

Then, a second processing liquid is supplied from the processing liquid supply part 72 to the processing liquid nozzle 71 and supplied through the opposing-member opening 54 of the top plate 5 located at the second position to the central part of the upper surface 91 of the substrate 9 that is being rotated (step S15). The second processing liquid supplied from the processing liquid nozzle 71 to the central part of the substrate 9 is spread radially outward from the central part of the substrate 9 and applied to the entire upper surface 91 of the substrate 9 by the rotation of the substrate 9. The second processing liquid is dispersed radially outward from the outer edge of the substrate 9 and received by the second guard 42 of the cup part 4.

With the first guard 41 located at the retracted position, the atmosphere in the inner space of the second guard 42 (hereinafter, referred to as a “second-guard inner space 420”) is discharged through the discharge port 44 to the outside of the housing 11. The atmosphere in the processing space 90 is discharged through the second-guard inner space 420 and the discharge port 44 to the outside of the housing 11. The atmosphere in the processing space 90 and the second-guard inner space 420 contains, for example, a mist of the second processing liquid. The second-guard inner space 420 is an annular space surrounded by the second guard 42 and the substrate holder 31. Specifically, the second-guard inner space 420 indicates a space that is below the second-guard canopy part 422, radially inward of the second-guard side wall part 421, and radially outward of the inner peripheral edge of the second-guard canopy part 422.

With the first guard 41 located at the retracted position, the purge gas flowing radially outward from the below-holder gap 310 also flows into the first-guard inner space 410 along the lower surface of the lower protruding part 315 and is discharged through the discharge port 44 to the outside of the housing 11. In the substrate processing apparatus 1, the second processing liquid is applied to the substrate 9 for a predetermined period of time, thus ending the processing of the substrate 9 using the second processing liquid. The second processing liquid may, for example, be a cleaning liquid such as deionized water or carbonated water, and in step S15, cleaning processing is performed on the substrate 9.

When the processing of the substrate 9 using the second processing liquid has ended, the supply of the second processing liquid from the processing liquid nozzle 71 is stopped. Then, the flow rate of the inert gas ejected from the gas supply part 73 through the side surface of the processing liquid nozzle 71 toward the nozzle gap 56 increases. The flow rate of the inert gas ejected from the lower end surface of the processing liquid nozzle 71 toward the processing space 90 also increases. Moreover, the rotation speed of the substrate 9 rotated by the substrate rotation mechanism 33 increases. Accordingly, the second processing liquid or the like remaining on the upper surface 91 of the substrate 9 moves radially outward, and is thus dispersed radially outward from the outer edge of the substrate 9 and received by the second guard 42 of the cup part 4. By continuing the rotation of the substrate 9 for a predetermined period of time, dry processing for removing the processing liquid from the upper surface 91 of the substrate 9 is performed (step S16).

When the dry processing of the substrate 9 has ended, the substrate rotation mechanism 33 stops rotating the substrate holder 31, the substrate 9, and the top plate 5 (step S17). Also, the supply of the inert gas from the gas supply part 73 to the nozzle gap 56, the processing space 90, and the below-holder gap 310 is stopped. Then, the opposing-member holder 61 is moved upward by the opposing-member elevating mechanism 62, and accordingly the top plate 5 is moved upward from the second position to the first position illustrated in FIG. 1 (step S18). The top plate 5 is spaced above the substrate holder 31 and held by the opposing-member holder 61. Thereafter, the substrate 9 is conveyed out of the housing 11 (step S19). In the substrate processing apparatus 1, the above-described steps S11 to S19 are sequentially performed on a plurality of substrates 9 to process the substrates 9 sequentially.

As described above, in the substrate processing apparatus 1, the top plate 5 located at the second position is held by the substrate holder 31 and rotated along with the substrate 9 and the substrate holder 31 by the substrate rotation mechanism 33. The gas supply part 73 supplies a treatment atmospheric gas to the processing space 90 between the top plate 5 and the substrate 9. This configuration allows a desired gas atmosphere to be created in the processing space 90 and allows the substrate 9 to be processed in this gas atmosphere. For example, when an inert gas is supplied to the processing space 90, the substrate 9 can be processed in an inert gas atmosphere (i.e., low oxygen atmosphere).

As described above, the substrate holder 31 includes the holding base part 311, the chucks 312, the engagement parts 313, and the base supporter 314. The chucks 312 and the engagement parts 313 are disposed on the upper surface of the holding base part 311, and the engagement parts 313 are located radially outward of the chucks 312. The holding base part 311 is supported from below by the base supporter 314 and extends radially outward of the base supporter 314. This configuration allows the chucks 312 and the engagement parts 313 to be readily arranged on the holding base part 311, and also makes it possible to reduce the diameter of the base supporter 314 and accordingly reduce the mass of the substrate holder 31. Consequently, the load on the substrate rotation mechanism 33 for rotating the substrate holder 31 can be reduced.

In the substrate processing apparatus 1, the cup part 4 includes the first guard 41, the second guard 42, the guard moving mechanism 43, and the discharge port 44 as described above. The guard moving mechanism 43 switches the guard for receiving the processing liquid from the substrate 9 between the first guard 41 and the second guard 42 by moving the first guard 41 between the liquid receiving position and the retracted position in the up-down direction. The gas in the first guard 41 and the second guard 42 are exhausted through the discharge port 44. Also, the generally annular lower protruding part 315 that extends radially outward from the base supporter 314 is provided below the holding base part 311. With the first guard 41 located at the retracted position, the lower protruding part 315 extends toward the inner peripheral edge of the first-guard canopy part 412.

The presence of the lower protruding part 315 allows the first-guard inner space 410 to be substantially isolated from the second-guard inner space 420 and suppresses the flow of a gas between the first guard 41 and the second guard 42 in the state in which the first guard 41 is located at the retracted position. This configuration suppresses the flow of the atmosphere in the first-guard inner space 410, which contains a mist or the like of the first processing liquid (e.g., chemical solution such as a polymer removing liquid or an etchant), into the second-guard inner space 420. Consequently, it is possible to suppress the occurrence of a situation in which a mist or the like of the first processing liquid adheres to the inner surface of the second guard 42 that receives the second processing liquid (e.g., cleaning liquid used in the cleaning processing of the substrate 9) and fouls the second guard 42, and to successively perform the processing of the substrate 9 using the second processing liquid.

As described above, the outer diameter of the top plate 5 is greater than the outer diameter of the holding base part 311. Thus, the processing space 90 can be easily maintained in the state in which the processing space 90 is filled with the desired treatment atmospheric gas. The outer diameter of the lower protruding part 315 is greater than the outer diameter of the holding base part 311 and less than or equal to the outer diameter of the top plate 5. Thus, the flow of a gas between the first guard 41 and the second guard 42 can be further suppressed in the state in which the first guard 41 is located at the retracted position.

Moreover, the top plate 5 includes the generally annular plate-like opposing-member canopy part 511 that opposes the upper surface 91 of the substrate 9, and the generally cylindrical opposing-member side wall part 512 that extends downward from the outer periphery of the opposing-member canopy part 511. The lower end of the opposing-member side wall part 512 is located below the upper surface of the holding base part 311 or at the same position as the upper surface of the holding base part 311 in the up-down direction. It is thus possible to suppress the entry of the atmosphere in the space around the processing space 90 (i.e., the space radially outward of the processing space 90) into the processing space 90 that is filled with the desired treatment atmospheric gas.

As described above, the gas supply part 73 is a purge gas supply part that supplies a purge gas to the below-holder gap 310 and forms an airflow of the purge gas flowing radially outward from the central part of the below-holder gap 310. The lower protruding part 315 is provided on the base supporter 314. In this configuration, the purge gas flowing radially outward from the below-holder gap 310 is guided to the first-guard inner space 410 along the lower surface of the lower protruding part 315 in both the state in which the first guard 41 is located at the liquid receiving position and the state in which the first guard 41 is located at the retracted position. Thus, the flow of the purge gas for sealing the rotary shaft 331 into the relatively clean second-guard inner space 420 can be suppressed. Consequently, it is possible to suppress the occurrence of a situation in which the second guard 42 that receives the second processing liquid (e.g., cleaning liquid used in the cleaning processing of the substrate 9) get fouled with the purge gas, and to successively perform the processing of the substrate 9 using the second processing liquid.

FIG. 7 is a cross-sectional view of a substrate processing apparatus 1a according to a second embodiment of the present invention. The substrate processing apparatus 1a has approximately the same configuration as that of the substrate processing apparatus 1 in FIG. 1, except that a lower protruding part 315a is located at a different position from the lower protruding part 315 in FIG. 1. In the following description, constituent elements of the substrate processing apparatus 1a that are similar to those of the substrate processing apparatus 1 are given the same reference numerals. FIG. 7 illustrates a state in which the top plate 5 is located at the aforementioned second position and the first guard 41 is located at the retracted position.

In the substrate processing apparatus 1a, the lower protruding part 315a is a generally annular member centered on the central axis J1 and extends radially outward from the side surface of the rotation-mechanism housing part 34. The lower protruding part 315a is located below and spaced from the holding base part 311. The outer diameter of the lower protruding part 315a is greater than the outer diameter of the holding base part 311 and less than or equal to the outer diameter of the top plate 5. In the example illustrated in FIG. 7, the lower protruding part 315a extends radially outward from the upper end of the rotation-mechanism housing part 34. The upper surface of the lower protruding part 315a is an inclined surface that is inclined downward outwardly in the radial direction.

As illustrated in FIG. 7, with the first guard 41 located at the retracted position, the lower protruding part 315a extending radially outward from the rotation-mechanism housing part 34 extends toward the inner peripheral edge of the first-guard canopy part 412. The outer periphery of the lower protruding part 315a and the inner periphery of the first-guard canopy part 412 are located at approximately the same position in the up-down direction and oppose each other in the radial direction with a slight gap therebetween. The procedure of processing performed on the substrate 9 by the substrate processing apparatus 1a is the same as the procedure of processing performed on the substrate 9 by the substrate processing apparatus 1.

In the substrate processing apparatus 1a, the presence of the lower protruding part 315a allows the first-guard inner space 410 to be substantially isolated from the second-guard inner space 420 and suppresses the flow of a gas between the first guard 41 and the second guard 42 in the state in which the first guard 41 is located at the retracted position. This configuration suppresses the flow of the atmosphere in the first-guard inner space 410, which contains a mist or the like of the first processing liquid (e.g., chemical solution such as a polymer removing liquid or an etchant), into the second-guard inner space 420. Consequently, it is possible to suppress the occurrence of a situation in which a mist or the like of the first processing liquid adheres to the inner surface of the second guard 42 that receives the second processing liquid (e.g., cleaning processing used in the cleaning processing of the substrate 9) and fouls the second guard 42, and to successively perform the processing of the substrate 9 using the second processing liquid.

As described above, the outer diameter of the top plate 5 is greater than the outer diameter of the holding base part 311. Thus, the processing space 90 can be easily maintained in the state in which the processing space 90 is filled with the desired treatment atmospheric gas. The outer diameter of the lower protruding part 315a is greater than the outer diameter of the holding base part 311 and less than or equal to the outer diameter of the top plate 5. Thus, the flow of a gas between the first guard 41 and the second guard 42 can be further suppressed in the state in which the first guard 41 is located at the retracted position.

FIG. 8 is a cross-sectional view of a substrate processing apparatus 1b according to a third embodiment of the present invention. The substrate processing apparatus 1b has approximately the same configuration as the configuration of the substrate processing apparatus 1 in FIG. 1, except that it includes, instead of the substrate holder 31 in FIG. 1, a substrate holder 31a that has a different configuration from that of the substrate holder 31. In the following description, constituent elements of the substrate processing apparatus 1b that are similar to those of the substrate processing apparatus 1 are given the same reference numerals. FIG. 8 illustrates a state in which the top plate 5 is located at the aforementioned second position and the first guard 41 is located at the retracted position.

As illustrated in FIG. 8, the substrate holder 31a includes a holding base part 311a, a plurality of chucks 312, a plurality of engagement parts 313, and a base supporter 314. The holding base part 311 a includes a base body part 316 and a base side wall part 317. The base body part 316 is a generally disk-shaped member centered on the central axis J1, and the chucks 312 and the engagement parts 313 are provided on the upper surface of the base body part 316. The base side wall part 317 is a generally cylindrical member centered on the central axis J1 and extends downward from the outer periphery of the base body part 316. The base side wall part 317 is disposed around and spaced radially outward from the base supporter 314.

In the substrate processing apparatus 1b, the base body part 316 extends radially outward of the base supporter 314 along the entire circumference. This configuration allows the chucks 312 and the engagement parts 313 to be readily disposed on the holding base part 311a, and also makes it possible to reduce the diameter of the base supporter 314 and accordingly reduce the mass of the substrate holder 31a. Consequently, the load on the substrate rotation mechanism 33 for rotating the substrate holder 31a can be reduced.

As illustrated in FIG. 8, with the top plate 5 located at the second position, the lower end of the opposing-member side wall part 512 is located below the upper surface of the holding base part 311 a of the substrate holder 31 a or at the same position as the upper surface of the holding base part 311 a in the up-down direction. With the first guard 41 located at the retracted position, the inner periphery of the first-guard canopy part 412 radially opposes the outer surface of the base side wall part 317 (i.e., outer surface of the holding base part 311 a). The procedure of processing performed on the substrate 9 by the substrate processing apparatus 1b is the same as the procedure of processing performed on the substrate 9 by the substrate processing apparatus 1.

In the substrate processing apparatus 1b, the inner periphery of the first-guard canopy part 412 radially opposes the outer surface of the holding base part 311a. Thus, with the first guard 41 located at the retracted position, the first-guard inner space 410 is substantially isolated from the second-guard inner space 420, and this suppresses the flow of a gas between the first guard 41 and the second guard 42. This configuration suppresses the entry of the atmosphere of the first-guard inner space 410, which contains a mist or the like of the first processing liquid (e.g. chemical solution such as a polymer removing liquid or an etchant), into the second-guard inner space 420. Consequently, it is possible to suppress the occurrence of a situation in which a mist or the like of the first processing liquid adheres to the inner surface of the second guard 42 that receives the second processing liquid (e.g., cleaning liquid used in the cleaning processing of the substrate 9) and fouls the second guard 42, and to successively perform the processing of the substrate 9 using the second processing liquid.

The substrate processing apparatuses 1, 1a, and 1b described above may be modified in various ways.

For example, the cup part 4 may further include one or a plurality of guards disposed around the second guard 42, in addition to the first guard 41 and the second guard 42. In this case, the guard for receiving the processing liquid from the substrate 9 is switched between the plurality of guards that include the first guard 41 and the second guard 42 in the same way as described above.

In the substrate processing apparatuses 1 and 1a in FIGS. 1 and 7, the opposing-member body 51 of the top plate 5 does not necessarily have to include the opposing-member side wall part 512, and the opposing-member canopy part 511 may form the opposing-member body 51. The outer diameters of the lower protruding parts 315 and 315a may be less than or equal to the outer diameter of the holding base part 311 or may be greater than the outer diameter of the top plate 5.

The configurations of the above-described preferred embodiments and variations may be appropriately combined as long as there are no mutual inconsistencies.

While the invention has been shown and described in detail, the foregoing description is in all aspects illustrative and not restrictive. It is therefore to be understood that numerous modifications and variations can be devised without departing from the scope of the invention. This application claims priority benefit under 35 U.S.C. Section 119 of Japanese Patent Application No. 2015-109311 filed in the Japan Patent Office on May 29, 2015, the entire disclosure of which is incorporated herein by reference.

### REFERENCE SIGNS LIST

1, 1a, 1b Substrate processing apparatus
4 Cup part
5 Top plate
9 Substrate
31, 31a Substrate holder
33 Substrate rotation mechanism
34 Rotation-mechanism housing part
41 First guard
42 Second guard
43 Guard moving mechanism
44 Discharge port
54 Opposing-member opening
72 Processing liquid supply part
73 Gas supply part
91 Upper surface (of substrate)
310 Below-holder gap
311, 311a Holding base part
312 Chuck
313 Engagement part
314 Base supporter
315, 315a Lower protruding part
411 First-guard side wall part
412 First-guard canopy part
421 Second-guard side wall part
422 Second-guard canopy part
511 Opposing-member canopy part
512 Opposing-member side wall part
J1 Central axis
S11 to S19 Step

1. A substrate processing apparatus for processing a substrate, comprising:
a substrate holder for holding a substrate in a horizontal position;
an opposing member that is held by said substrate holder, opposes an upper surface of said substrate, and has an opposing-member opening in a central part;
a substrate rotation mechanism disposed below said substrate holder and for rotating said substrate and said opposing member along with said substrate holder about a central axis pointing in an up-down direction;
a rotation-mechanism housing part for housing said substrate rotation mechanism below said substrate holder;
a processing liquid supply part for supplying a processing liquid to said upper surface of said substrate through said opposing-member opening; and
a cup part disposed around said substrate holder and for receiving a processing liquid from said substrate,
wherein said substrate holder includes:
a base supporter;
a disk-shaped holding base part supported from below by said base supporter and extending radially outward of said base supporter;
a plurality of chucks that are disposed on an upper surface of said holding base part and support said substrate; and
an opposing-member supporter that is disposed radially outward of said plurality of chucks on said upper surface of said holding base part and supports said opposing member,
said cup part includes:
a first guard having a cylindrical first-guard side wall part and an annular plate-like first-guard canopy part that extends radially inward from an upper end portion of said first-guard side wall part;
a second guard having a cylindrical second-guard side wall part that is located radially outward of said first-guard side wall part, and an annular plate-like second-guard canopy part that extends radially inward from an upper end portion of said second-guard side wall part above said first-guard canopy part;
a guard moving mechanism for switching a guard for receiving a processing liquid from said substrate between said first guard and said second guard by moving said first guard in said up-down direction between a liquid receiving position at which said first guard receives the processing liquid from said substrate and a retracted position that is below said liquid receiving position; and
a discharge port through which gas in said first guard and said second guard is exhausted,
an inner diameter of said first-guard canopy part and an inner diameter of said second-guard canopy part are greater than an outer diameter of said holding base part and an outer diameter of said opposing member, and
an annular lower protruding part is provided to extend radially outward from either said base supporter or said rotation-mechanism housing part below said holding base part toward an inner peripheral edge of said first-guard canopy part in a state in which said first guard is located at said retracted position.

2. The substrate processing apparatus according to claim 1, further comprising:
a purge gas supply part for supplying a purge gas to a space between said base supporter of said substrate holder and said rotation-mechanism housing part and producing an airflow flowing radially outward from the central part,
wherein said lower protruding part is provided on said base supporter.

3. The substrate processing apparatus according to claim 2, wherein
the outer diameter of said opposing member is greater than the outer diameter of said holding base part, and
an outer diameter of said lower protruding part is greater than the outer diameter of said holding base part and less than or equal to the outer diameter of said opposing member.

4. The substrate processing apparatus according to claim 3, wherein
said opposing member includes:
an annular plate-like opposing-member canopy part that opposes said upper surface of said substrate and has said opposing-member opening in the central part; and
a cylindrical opposing-member side wall part that extends downward from an outer periphery of said opposing-member canopy part, and
a lower end of said opposing-member side wall part is located below said upper surface of said holding base part or at the same position as said upper surface of said holding base part in said up-down direction.

5. The substrate processing apparatus according to claim 1, wherein
the outer diameter of said opposing member is greater than the outer diameter of said holding base part, and
an outer diameter of said lower protruding part is greater than the outer diameter of said holding base part and less than or equal to the outer diameter of said opposing member.

6. The substrate processing apparatus according to claim 5, wherein
said opposing member includes:
an annular plate-like opposing-member canopy part that opposes said upper surface of said substrate and has said opposing-member opening in the central part; and
a cylindrical opposing-member side wall part that extends downward from an outer periphery of said opposing-member canopy part, and
a lower end of said opposing-member side wall part is located below said upper surface of said holding base part or at the same position as said upper surface of said holding base part in said up-down direction.

7. The substrate processing apparatus according to claim 1, wherein
said opposing member includes:
an annular plate-like opposing-member canopy part that opposes said upper surface of said substrate and has said opposing-member opening in the central part; and
a cylindrical opposing-member side wall part that extends downward from an outer periphery of said opposing-member canopy part, and
a lower end of said opposing-member side wall part is located below said upper surface of said holding base part or at the same position as said upper surface of said holding base part in said up-down direction.

8. A substrate processing apparatus for processing a substrate, comprising:
a substrate holder for holding a substrate in a horizontal position;
an opposing member that is held by said substrate holder, opposes an upper surface of said substrate, and has an opposing-member opening in a central part;
a substrate rotation mechanism disposed below said substrate holder and for rotating said substrate along with said substrate holder about a central axis pointing in an up-down direction;
a processing liquid supply part for supplying a processing liquid to said upper surface of said substrate through said opposing-member opening; and
a cup part disposed around said substrate holder and for receiving a processing liquid from said substrate,
wherein said substrate holder includes:
a holding base part;
a plurality of chucks that are disposed on an upper surface of said holding base part and support said substrate; and
an opposing-member supporter that is disposed radially outward of said plurality of chucks on said upper surface of said holding base part and supports said opposing member,
said cup part includes:
a first guard having a cylindrical first-guard side wall part and an annular plate-like first-guard canopy part that extends radially inward from an upper end portion of said first-guard side wall part;
a second guard having a cylindrical second-guard side wall part that is located radially outward of said first-guard side wall part, and an annular plate-like second-guard canopy part that extends radially inward from an upper end portion of said second-guard side wall part above said first-guard canopy part;
a guard moving mechanism for switching a guard for receiving a processing liquid from said substrate between said first guard and said second guard by moving said first guard in said up-down direction between a liquid receiving position at which said first guard receives the processing liquid from said substrate and a retracted position that is below said liquid receiving position; and
a discharge port through which gas in said first guard and said second guard is exhausted,
said opposing member includes:
an annular plate-like opposing-member canopy part that opposes said upper surface of said substrate and has said opposing-member opening in the central part; and
a cylindrical opposing-member side wall part that extends downward from an outer periphery of said opposing-member canopy part,
an inner diameter of said first-guard canopy part and an inner diameter of said second-guard canopy part are greater than an outer diameter of said holding base part and an outer diameter of said opposing member,
a lower end of said opposing-member side wall part is located below said upper surface of said holding base part or at the same position as said upper surface of said holding base part in said up-down direction, and
an inner peripheral edge of said first-guard canopy part opposes an outer surface of said holding base part in a radial direction in a state in which said first guard is located at said retracted position.
